(19) United States
(12) Patent Application Publication
(10) Pub. No.: US 2005/0034981 A1
(43) Pub. Date: Feb. 17, 2005

(54) Cathodic sputtering apparatus

(76) Inventors: Frank Fuchs, Geiselbach (DE); Stefan Bangert, Steinau (DE); Ralph Lindenberg, Budingen (DE); Helmut Grimm, Darmstadt (DE); Tobias Stolley, Frankfurt am Main (DE); Uwe Schussler, Aschaffenburg (DE)

Correspondence Address: FULBRIGHT & JAWORSKI, LLP, 666 FIFTH AVE, NEW YORK, NY, 10103-3198, US

(21) Appl. No.: 10/851,998

(22) Filed: May 20, 2004

(30) Foreign Application Priority Data
Aug. 8, 2003 (DE) 103 36 422.6

(51) Int. Cl. C23C 14/00

(52) U.S. Cl. 204/298.21; 204/298.22

(57) ABSTRACT

The invention relates to a cathodic sputtering apparatus (8) for coating substrates (17) in a vacuum, comprising an essentially tubular support for the material to be sputtered (2) which is rotatable about its longitudinal axis, a cooling system which is suitable for circulating a cooling medium in the tubular support (2) in conjunction with a cooling device external to the support (2), a device for connecting to an electrical power circuit, and a device for the rotary drive of the tubular support about its longitudinal axis. This apparatus also is provided with a magnet system which extends along the axis for the magnetic confinement of a plasma which is provided near a target made of the material to be sputtered, the magnet system being composed of pole shoes (9, 10), magnet yokes (12, 13) made of magnetically permeable metal, and magnetization means (5) which are suitable for generating a magnetic flux in the magnet system. The magnet poles of one polarity in the magnet system are situated outside the tubular target support (2) and enclose same in a frame-like manner, and the opposite magnetic poles are provided in the tubular, rotatable target support (2).

The invention relates to an apparatus for coating substrates by cathodic sputtering according to the preamble of Claim 1.

Apparatuses for cathodic sputtering find application in vacuum coating technology. A magnetron sputtering cathode comprises an electrically conductive, generally metallic material supply, referred to as the target, which is sputtered and in this manner applied to a substrate which is appropriately situated with respect to the cathode. A magnet system located behind the target generates a magnetic field which permeates the target and forms a magnetic tunnel on the target surface in the shape of a continuous loop. The interaction of the electrical and magnetic fields causes the electrons in the plasma to move in a spiral fashion and to drift at a high velocity transverse to the magnetic field within this tunnel. The electrons are hereby retained on a long track near the target surface and acquire a high kinetic energy, enabling them to ionize the neutral atoms of the process gas. Essentially, the electrostatic forces of attraction from the target in the cathode at negative potential act on the positively charged ions in the process gas. This causes the ions to be accelerated toward the target surface, where they eject atoms from the target by pulse transfer. Due to the fact that a large number of atoms per unit time is emitted from the target surface, a particle stream is obtained which behaves essentially like a metallic vapor when a metallic target is used. This metallic vapor flows to the substrate, among other parts, on the surface of which a thin layer of target material grows.

The mixing of reactive gases such as oxygen or nitrogen, for example, with the process gas creates metallic oxides or metallic nitrides. In this coating process referred to as reactive sputtering, not only the substrates and the shields, but also the areas of the target not eroded by the sputtering process are gradually coated with the electrically nonconductive reaction products (redeposition). On the surface of the target, which typically is at a potential of several hundred volts, very thin dielectric layers grow whose surfaces have a plasma potential of only several tens of volts, both referenced potentials being negative with respect to ground. The high electrical fields thus generated in this coating material cause a dielectric breakdown, known to those skilled in the art as “arcing,” which is visible as electrical sparkovers. The arcing disturbs the uniformity of the plasma discharge and the quality of the layer deposited on the substrate, among other parameters, for which reason the generation of sparkovers is avoided. A solution to this problem involves the use of cathodes having cylindrical rotatable targets. During the sputtering process the target rotates continuously about its longitudinal axis in front of the static magnet system, so that the coating material back-scattered to the target does not have sufficient time to form a continuous layer. When the target areas which are slightly coated with the dielectric material re-enter the plasma zone after one full revolution, material is removed anew from the target surface, so that such a target is substantially free of dielectric coatings.

If the plasma loop is compressed onto too small a subarea of the target surface as a result of the narrowly designed magnetic field, the power introduced into the target by the sputtering process is concentrated on a small surface area. This results in thermal stresses, or may also cause localized melting of the target. The surface power density may be lowered by broadening the magnetic tunnel, with the result that the plasma acts on a larger area of the target surface. For sputtering cathodes having cylindrical targets, however, it is not so simple to place the yoke arms of the magnet system far enough apart from one another, since space is restricted due to the magnet system being housed within the cylindrical target support. On account of the geometry of the target support, the magnetic field formed in front of the target surface no longer has sufficient intensity when the yoke arms are too far apart inside the target support, since then the portion of the magnetic field with the higher field intensities extends within the target support. Providing a solution to this problem is a further aspect of the present invention.

Such apparatuses are adequately known to those skilled in the art, and are described in EP 070 899, for example. The cylindrical target is rotatably mounted so that new target material can be introduced into the sputtering zone, in order to achieve a longer useful life of the cathode through a larger supply of target material, or also to enable a rapid change from one target material to another.

In these known apparatuses the magnets are designed as permanent magnets, whereby the magnets necessary for guiding the electrons in the plasma on a track in the form of a continuous loop parallel to the longitudinal axis of the tubular target, known as a “racetrack,” are mounted inside the target support. In one variant embodiment, two tubular cathodes held parallel at a distance from one another form the longitudinal tracks of a racetrack, the two essentially straight tracks being connected to a closed curve at the ends of each of the cylindrical targets by means of two U-shaped magnets situated between the two targets. The magnet systems inside the cylindrical target supports are designed mirror-symmetrically, so that like poles of one polarity are oppositely situated on the sides of this apparatus which face toward one another, and like poles of the other polarity are situated on the outer sides which face away from one another. The U-shaped permanent magnets provided between the two targets are oriented in such a way that they connect the magnetic fields inside both target supports to form a closed magnetic tunnel.

A disadvantage of this apparatus is that material located on the ends of the cylindrical targets is not removed by the cathodic sputtering, and therefore cannot be used for coating of the substrates. Furthermore, there is a problem in that the sputtering rate of the target material is kept low by the narrow plasma regions created by narrow magnetic tunnels. However, it is not possible to arbitrarily increase the distance between the two poles of the magnet system in the tubular target support. The sputtering rate could also be achieved by increasing the electrical power with which the plasma discharge is operated. However, this has the disadvantage that a very high thermal stress on the target material and target support is created in the narrow plasma loops, which for brittle target materials can lead to thermal stress cracks, or for materials having low melting points can result in localized melting of the target material. If suitably formed target tiles are connected to the tubular target support by a type of tin solder, the introduction of high localized temperature can cause melting off of the target tiles.

Furthermore, an apparatus for carrying out vacuum technology processes in electrical discharges intensified by a magnetic field has been proposed (DD 123 952) which comprises a magnetic field-generating device, and a target at negative potential and an anode between which an electrical discharge arcs, whereby the magnetic field-generating device with its pole shoes has an annular design concentric to the cathode and, depending on the vacuum technology process to be carried out, is mounted inside the tubular target or externally mounted enclosing same, and generates nonhomogeneous toroidal magnetic fields, delimited in the axial direction, whose main field direction in the region of the target is oriented parallel to the axial direction of the target. When the magnetic field-generating device is provided inside the target the anode encloses the target in a tubular fashion, and when the magnetic field-generating device is provided surrounding the target the anode is installed in the target as a tube or solid material, whereby the magnetic field-generating device, the tubular target, and the anode are movable with respect to one another. In all of the exemplary embodiments disclosed, the device generating the magnetic field is a single piece and is provided only on the side of the target opposite the side of the target to be sputtered.

Furthermore, a device for high-speed sputtering according to the plasmatron principle is known (DD 217 964) which comprises a magnetic field-generating device having an annular gap, a cooled tubular target, and an anode, whereby the magnetic field-generating device has a long continuous annular gap and is situated in the target in such a way that the long axis of the magnetic field-generating device runs parallel to the target axis, and an anode encloses the target so that the annular gap region is open, and the distance between the anode and the target surface may be set at a fixed value using an adjustment device. A drive is provided between the target and the magnetic field-generating device to produce a relative motion about the long axis, and an apparatus is provided on the magnetic field-generating device for changing the distance between the magnetic field-generating device and the target. In this sputtering apparatus as well, the magnetic field-generating device is a single piece and is provided only on the side of the target opposite the side of the target to be sputtered.

A cathodic sputtering apparatus is also known (DE 27 07 144) which comprises a cathode having a surface to be sputtered, and a magnetic device located near the cathode and on the side opposite the surface to be sputtered for generating magnetic lines of force, at least some of which enter and exit the surface to be sputtered at spaced-apart intersections, between which the lines of force form continuously arched segments at a distance from the surface to be sputtered. The lines of force together with the surface to be sputtered form a boundary for an enclosed area, thus creating a tunnel-shaped region situated above a thus defined path on the surface to be sputtered. Charged particles show a tendency to be restrained in the tunnel-shaped region and to move along same. The cathodic sputtering apparatus also has an anode in the vicinity of the cathode, and has a connection to a source of electrical power for the cathode and the anode, whereby at least the surface to be sputtered is situated inside an evacuatable container, a direction of motion being provided for producing a relative motion between the magnetic field and the surface to be sputtered while maintaining its spatial relationship, and the referenced path covering the surface to be sputtered in a surface area that is greater than the surface area occupied by the resting path.

In the cylindrical cathodic sputtering apparatus described here, the magnetic device attached to a cylindrical support may be rotated as well as moved back and forth so that it is able to produce the sputtering on the entire surface. However, it is also possible to select specific areas with the entire magnetic device being provided on one side of the target. In all the exemplary embodiments disclosed, however, the device generating a magnetic field is a single piece and is provided on only one side of the target.

Also included in the prior art is an apparatus for cathodic sputtering in a vacuum (EP 0 461 035), comprising a hollow body in the form of a rotational solid which is rotatable about its axis, having a side wall extending along the axis and two end faces essentially perpendicular to the axis, the hollow body being formed, at least on the exterior of its side wall, from material to be sputtered; a magnetic circuit for magnetic confinement which is provided near the target; poles made partially of magnetically permeable metal and magnetization means, which are suitable for generating a magnetic flux in the magnetic circuit; a device for connecting to a cooling circuit for circulating a cooling liquid in the hollow body; a device for connecting to an electrical supply circuit; a drive for rotating the hollow body about its axis, the magnetic circuit extending peripherally with respect to the hollow body, the magnetization means being provided outside same, and the poles of the magnetic circuit being provided along two generating lines of this hollow body; and an arch in the side wall of the hollow body, located between these two generating lines, which forms the sputtering area of the target.

In this cathodic sputtering apparatus having cylindrical targets, the device generating the magnetic field comprising permanent magnets, electromagnets, magnet yokes, and pole shoes is situated essentially outside the target to ensure an increased flow of coolant through the interior of the target support, the magnetic poles of both polarities which generate the magnetic field being situated outside the target.

Lastly, an apparatus for coating a substrate by sputtering of the surface of a rotatable tubular target using electrical energy has been proposed (DE 196 23 359) in which pole shoes made of magnetically conductive material are situated in the target, whereby outside the target a magnetic flux guide element is provided which has three pole shoes oriented toward the hollow body which are interconnected via magnets which transmit the magnetic field through the target across narrow gaps to the pole shoes situated inside the target and which generate a tunnel-shaped magnetic field on the side of the apparatus facing the substrate, so that the magnetic field lines emanating from and returning to the sputtering surface form a discharge region having the shape of a continuous loop.

In this cathodic sputtering apparatus having cylindrical targets, the magnetic field-generating device which comprises permanent magnets, pole shoes, and magnet yokes having magnetic poles of two polarities is situated outside the targets, and inside the target only parts made of magnetically permeable metal are provided which conduct the magnetic force lines through the cylindrical target, whereby the magnetic field-generating device is located diametrically opposite from the sputtering area and therefore is not exposed to the thermal stress introduced into the target by the sputtering process. However, in the region of the active zone of the target in which the target erosion takes place, the magnetic field generated by this disclosed magnet system is not substantially different from magnetic fields which can be generated by magnet systems located exclusively inside the rotatable tubular target support, so that it is not possible to broaden or intensify the magnetic tunnel in front of the rotatable tubular target.

The object of the present invention is to design an apparatus of the aforementioned type in such a way that the magnetic field intensity is increased in the region of the active zone of the target in which the target erosion takes place, and the active zone is also made wider in order to increase the sputtering rate of target material and simultaneously lower the thermal power density which is introduced into the target material.

This object is achieved according to the invention by a magnetron for cathodic sputtering, comprising a tubular target with a target support which is rotatable about its longitudinal axis; a magnet system for magnetic confinement of plasma directly adjacent to the target, and magnetic field guide elements made of magnetically permeable metal and magnetization means for generating a magnetic field in the magnet system; and a cooling system for the target and an electrical power circuit. The magnet system is composed of two parts, the one part having one magnetic polarity being situated inside the tubular target support, and the second part of the magnet system having the opposite polarity enclosing the tubular target support in a frame-like manner without an electrical contact to the target.

The part of the magnet system provided outside the tubular target enables higher magnetic field intensities to be generated in front of the target, thereby achieving a higher plasma density. The two parts of the magnet system are fabricated in such a way that the magnetic field lines which do not define the plasma loop outside the tubular target are returned from the pole surfaces of the magnetization means to the particular oppositely situated magnetic pole facing away from the plasma, by the shortest path via magnet yokes. To this end, the parts of the pole shoes inside and outside the tubular target face one another separated by the shortest possible distance. It is thus possible to produce a continuous, tunnel-shaped magnetic field distribution situated in front of the tubular target without magnetic fields emanating from the magnetic field guide elements in the back part of the cathode, which could lead to the creation of subplasma. For a magnet system located exclusively inside the tubular target, for expanding the sputtering area on the target it would not be possible to position the two magnetic poles at a greater distance from one another without such long-term weakening of the outwardly emanating, tunnel-shaped magnetic field for defining the plasma zone that reliable ignition of the plasma would no longer be ensured, and it would no longer be possible to achieve the magnetic confinement of the plasma. In addition, if the magnetic poles are too far apart the magnetic field lines may assume a curved shape in which the field intensities required for confining plasma are situated inside the tubular target, with the result that magnetic confinement of plasma in front of the target is no longer possible.

A further advantage of the magnet system according to the invention is the possibility of placing the frame-shaped portion of the magnet system, which is provided outside the tubular target, on a box-shaped cathode enclosure totally surrounding the region outside the active zone of the target in which the target erosion occurs. Feeding the sputter gas mixture or components thereof into this box-shaped cathode enclosure causes the gas to pass through the narrow gaps between the magnetic pole shoe and the target surface and to enter directly into the plasma discharge, where it is at least partially ionized. In this manner the reactive gases from the process gas mixture may be more intensively activated, thereby facilitating the chemical reaction between the target material and the reactive gas and obtaining a higher quality of the deposited layers.

This type of gas feed and the partial enclosure of the target provides the additional advantage that, as a result of the higher flow rate of the gas mixture or the selected gas components through the narrow gap, the material sputtered from the target is prevented from being redeposited on the target surface outside and near the region of the active zone of the target where the target erosion occurs. For reactive processes, material compositions are produced which are electrically nonconductive and which can thus negatively affect the plasma discharge. The box-shaped cathode enclosure prevents the sputtered reactive material or contaminants from reaching target areas located at a further distance, outside the active zone of the target in which the target erosion occurs. The apparatus according to the invention therefore has high operational reliability and allows a particularly stable, arc-free coating process.

The magnet system may contain permanent magnets, as is common with comparable apparatuses, but it is also possible to use one or more electromagnets.

The invention is described in greater detail below with reference to drawings, resulting in further features, particulars, and advantages of the invention independent of the summary in the Claims.

The following are shown in schematic representation:

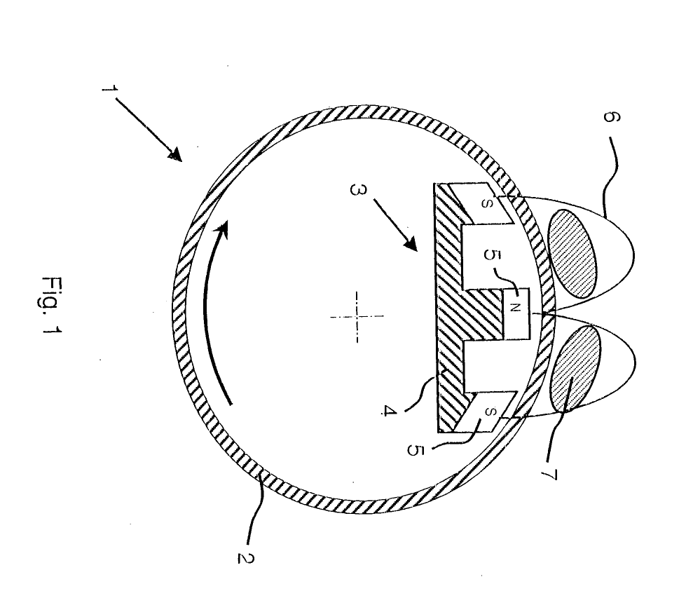

FIG. 1 shows a cross section through a cathodic sputtering apparatus having a rotatable target according to the prior art;

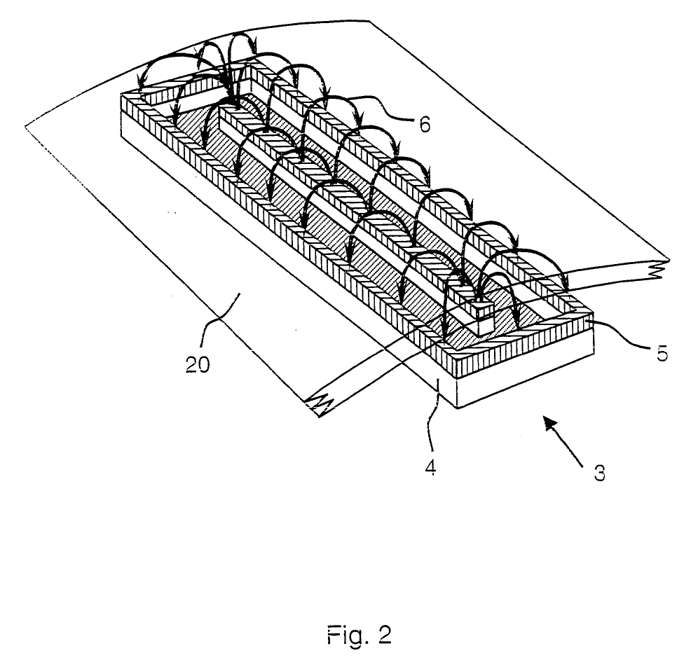

FIG. 2 shows in perspective illustration a diagram of a magnet assembly according to the prior art mounted under a target having a curved lateral surface;

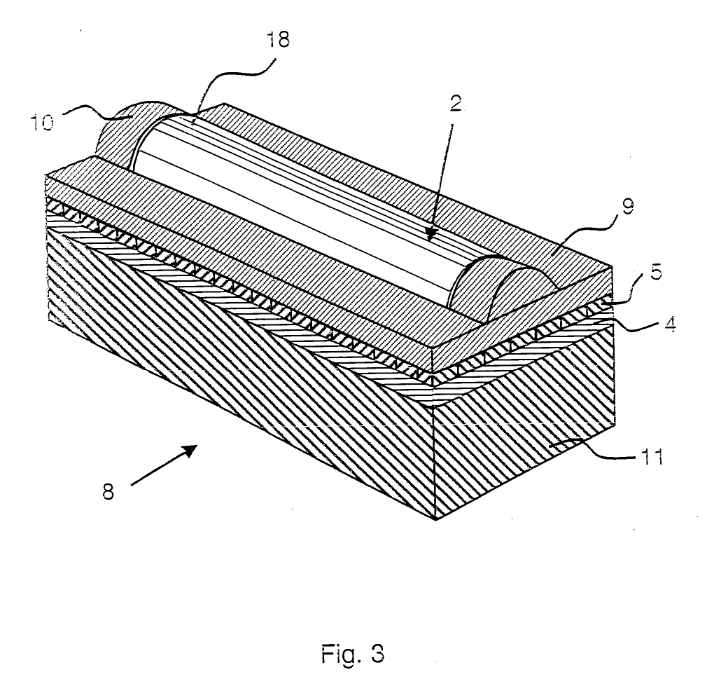

FIG. 3 shows a perspective view of a cathodic sputtering apparatus according to the invention having a rotatable target which is partially enclosed by the external component of the magnet system;

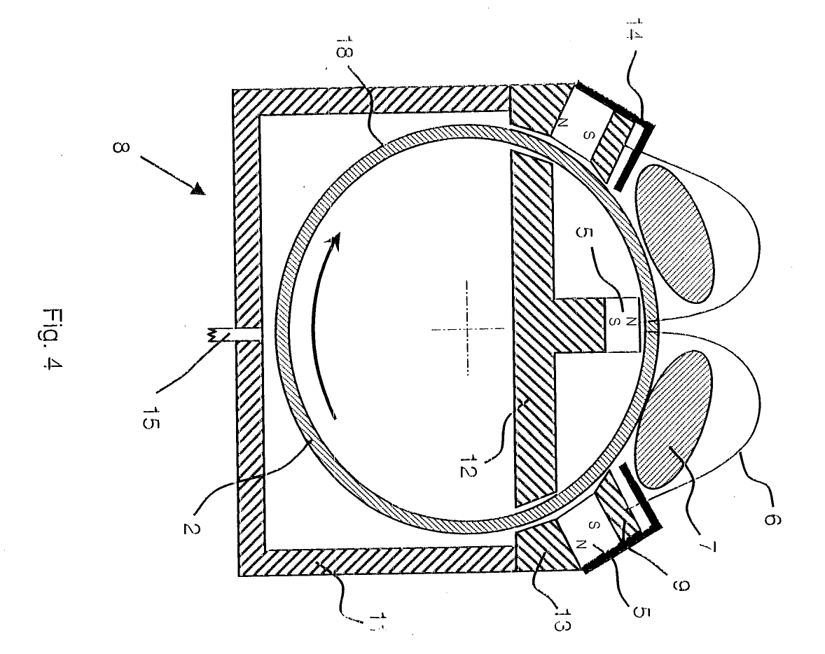

FIG. 4 shows a cross section through a cathodic sputtering apparatus according to the invention having a rotatable target; and

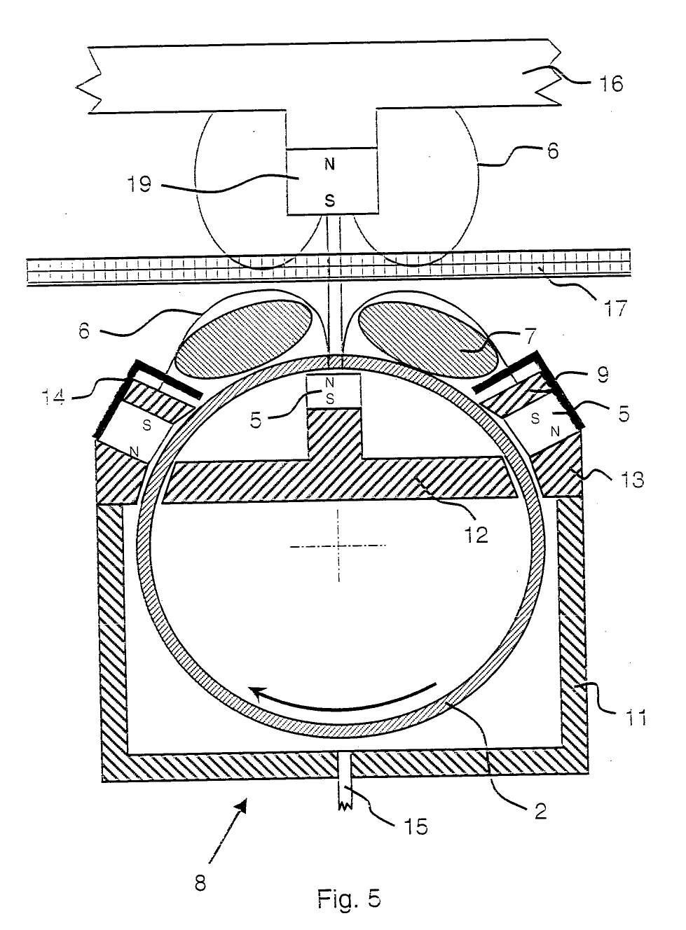

FIG. 5 shows a cross section through a cathodic sputtering apparatus according to the invention having a rotatable target in a further embodiment of the magnet system.

In the following figures, identical or corresponding elements are provided with the same reference numbers.

For all the apparatuses described below, the surfaces to be sputtered are in a vacuum, even if the illustrations of vacuum chambers, vacuum pumps, valves, locks, and pressure measuring devices have been omitted. The means according to the prior art necessary for cooling, rotation of the target, and electrical contacting have likewise been omitted.

FIG. 1 schematically illustrates a cross section through a cathodic sputtering apparatus (1) having a rotatable cylindrical target with a target support (2) according to the prior art. The internally mounted magnet system (3) comprising a magnet yoke (4) made of a magnetically permeable metal and a plurality of permanent magnets (5) is situated near the inner tubular wall of the cylindrical target with a target support (2). Magnetic field lines (6) emanate from the pole surfaces of the permanent magnets (5) facing away from the magnet yoke and penetrate the tubular target with a target support (2); in the diagram these two components have not been individually illustrated. Between the magnetic poles of differing polarity a magnetic field is formed which has the sketched magnetic field lines (6) for confining a plasma discharge (7). The means and devices necessary for operation, such as for cooling and for rotating the target, attachment of the magnet system (3), and the connections for the electrical power supply to the target, are not illustrated in FIG. 1. The arrow shown in FIG. 1 is intended to show the possibility for the target to rotate about the rotational axis indicated by the center cross, although the direction of rotation may be in the same or opposite direction as the arrow.

FIG. 2 shows in diagram form a magnet assembly according to the prior art, situated below a target having a curved lateral surface, illustrated only in sectional view, with the magnetic field penetrating the target shown in perspective view. The magnet system (3) assumes an approximately rectangular shape with three pole shoes situated parallel to the lateral surface of the target (20), the center pole shoe terminating in the end region of the magnet system at approximately the same distance from the outer pole shoe as the width it occupies on the longitudinally extended straight section. In this manner the magnet system (3) creates a magnetic tunnel, by means of the sketched field lines (6), which encloses the plasma (not shown here) on a track in the shape of a closed loop composed of two straight sections and two curved sections, parallel to the longitudinal axis of the tubular target, known as the “racetrack.” In the end region of the target the plasma is turned back onto the track running parallel to and in the opposite direction of the first track by means of a semicircular magnetic tunnel, thereby closing the loop after the second curve is passed. The magnetic field does not emanate into the space on the pole side of the magnetization means (5) facing the magnet yoke, since the magnetic field is completely absorbed in the soft-magnetic magnet yokes having higher magnetic susceptibility and is returned to the opposite pole.

FIG. 3 schematically illustrates the essential elements of a cathodic sputtering apparatus (8) according to the invention, having a rotatable cylindrical target with a target support (2). The magnetic pole of one polarity, not visible, is situated inside the target (2) under the apex line of the cylindrical target (2), while the magnets (5) which constitute the magnetic opposite pole are situated outside and around the target (2). The magnetic flux emanating from the pole surfaces of the magnets (5) toward the exterior portion of the magnet yoke (4) is conducted by same to the interior part of the magnet yoke which is not visible, and is conducted through the nonmagnetic target. The magnetic flux (not shown) exiting from the pole surfaces of the magnets (5) toward the exterior pole shoe (9, 10) is conducted through this pole shoe (9, 10) to the outer target surface (18) in such a way that a portion of the magnetic field lines penetrate into the target, whereas the larger portion is directed in an arched shape in front of the target to the apex line of the cylindrical target (2), where it passes through the target and reaches the interior magnetic pole.

In order to shape the magnetic field in the two end regions of the cylindrical target (2) into a semicircular magnetic tunnel which forms the plasma into a continuous loop with two elongated plasma zones running approximately parallel to one another, the pole shoe (10) on the end faces of the cathode (8) is adapted to the curvature of the cylindrical target (2). The magnetization means (5) on the end faces of the cathode (8) may be positioned, as shown, in a straight line, and the magnetic flux is conducted through the pole shoe (10) to the target in a suitable manner. To achieve special effects or shapes of the curved magnetic field, however, the magnets (5) on the end faces of the cathode (8) may also be positioned on a curved line which lies in a plane perpendicular to the longitudinal axis of the cylindrical target.

The back side of the cathode is surrounded by a box-shaped shield or cathode enclosure (11) which at the same time may also be used as a support for the exterior component of the magnet system. The suspension for the rotatable cylindrical target (2), the drive for the rotation, and the supply lines for electrical energy and coolant are situated inside the cathode enclosure (11) so that these elements, among others, are protected from being coated by material ablated from the target.

The magnet system according to the invention may contain one or more magnet coils or permanent magnets, and has a simple technical solution particularly for the external portion, since current feedthrough need not be conducted through rotating parts.

FIG. 4 shows a cross section through the sputtering apparatus (8) according to the invention. The target with a target support (2) is surrounded by a box-shaped shield or cathode enclosure (11) which at the same time may also be used as a support for the exterior portion of the magnet system (5, 9, 13) and for a shield (14). The yoke for the magnet system is divided into an internal component (12) and an external component (13). A pole shoe (9) is provided for suitably conducting the magnetic field lines (6) from the external portion of the magnet system toward the target (2). This pole shoe may be protected from coating and damage by using a shield (14) made of nonmagnetic material. The magnetic field lines (6) exit the pole shoe (9) near the target (2) and describe an arch in order to enter the interiorly situated magnetic pole of opposite polarity. From there, the magnetic field lines are conducted in the interior portion of the yoke (12) to the inside of the tubular rotatable target where they penetrate the nonmagnetic target and target support (2) and, because of the small distance to the external portion of the magnet yoke (13), return to the externally situated magnetization means (5) with no additional loss of field intensity.

The box-shaped shield or cathode enclosure (11) may on the one hand support the external portion of the magnet system, and on the other hand may accommodate the support for the rotatable target with a target support (2), and may also be used for the directed feed of the process gas flow. For the latter, a gas feed (15) is provided on the back side of the box-shaped shield or cathode enclosure (11) through which the reactive gas, inert gas, or process gas mixture passes into the interior of the cathode enclosure (11). The gas flows through the narrow gaps between the outer target surface (18) and the external portions of the yoke (13), magnetization means (5), the pole shoes (9), and the shields (14). In this manner the process gas is introduced directly into the plasma region (7), thereby achieving a higher ionization rate and thus, for reactive coating processes, an improved chemical reaction between the target material and the reactive gas.

The arrow illustrated in FIG. 4 is intended to show the possibility of rotating the target about the rotational axis indicated by the central cross, although the direction of rotation may be in the same or opposite direction as the arrow.

As shown in FIG. 4, the external magnets (5), the pole shoes (9) parallel to the lateral surface of the target, and the shields (14) may be inclined toward the center magnet of the magnet system, whereby, for example, the outer portion of the magnet yoke (13) or the pole shoe (9) (not shown) have a suitable cross section. Likewise, these parts may also be provided with rectangular cross sections, as shown in FIG. 3, so that their front surfaces oriented toward the substrate run at a right angle to the plane defined by the midpoint of the internal center magnets (5) and the rotational axis.

Another preferred embodiment of the invention, shown in FIG. 5, also contains a mounting (16) provided behind the substrate (17) for the control magnetization means (19), whose distance to the cathode (8) and/or polarity may be varied. This mounting may be used to modify the plasma (7)-conducting magnetic field (6) in the region of the substrate (17) surface to be coated, so that the plasma density distribution may be adapted to special process controls, and/or the plasma is able to act on the substrate surface. As shown in FIG. 5. the control magnetization means (19) may be composed of permanent magnets, but may also be provided with a magnet coil, whereby the mounting (16) is provided with a pole shoe or iron core (not shown) instead of permanent magnets (19).

The arrow illustrated in FIG. 5 is intended to show the possibility of rotating the target about the rotational axis indicated by the central cross, although the direction of rotation may be in the same or opposite direction as the arrow.

### List of Reference Numbers

1 Cathodic sputtering apparatus having a rotatable target, cathode
2 Cylindrical target with a target support
3 Magnet system
4 Magnetic field guide element, magnet yoke
5 Magnetization means, permanent magnet
6 Magnetic field lines
7 Plasma discharge, plasma
8 Cathodic sputtering apparatus, cathode according to the invention
9 Pole shoe in the longitudinal portion outside the magnet assembly
10 Pole shoe on the end portion outside the magnet assembly
11 Box-shaped cathode enclosure or shield
12 Component of the inventive magnet yoke situated inside the target support
13 External portion of the inventive magnet yoke
14 Shield
15 Gas feed
16 Mounting for the control magnetization means
17 Substrate
18 Outer target surface
19 Control magnetization means
20 Section of a target having a curved lateral surface

1. An apparatus for cathodic sputtering for coating substrates in a vacuum, comprising an essentially tubular support for the material to be sputtered which is rotatable about its longitudinal axis; a magnet system which extends along the longitudinal axis for magnetic confinement of a plasma which is provided near a target made of the material to be sputtered, the magnet system being composed of pole shoes, magnet yokes made of magnetically permeable metal, and magnetization means suitable for generating a magnetic flux in the magnet system; a cooling system suitable for circulating a cooling medium in the tubular support in conjunction with a cooling device external to the support; a device for connecting to an electrical power circuit; and a device for the rotary drive of the tubular rotatable support about its longitudinal axis, wherein the magnetic poles of one polarity in the magnet system are situated outside the tubular, rotatable support and enclose same.

2. An apparatus according to claim 1, wherein the external pole shoes in the end region of the cylindrical target have a shape that is essentially adapted to the curvature of the target.

3. An apparatus according to claim 1, wherein the external magnetization means are situated on the front faces of the magnet system in a plane perpendicular to the rotational axis of the target, on a curved line in this plane.

4. An apparatus according to claim 1, wherein the externally situated magnet system is connected to a cathode enclosure which hemispherically surrounds the cathode.

5. An apparatus according to claim 4, wherein the process gas or portions of a process gas mixture are fed through the interior of the cathode enclosure which hemispherically surrounds the cathode.

6. An apparatus according to claim 1, wherein a control magnet system is provided opposite the cathode-magnet system and behind the substrate.

7. An apparatus according to claim 6, wherein the control magnet system contains permanent magnets.

8. An apparatus according to claim 6, wherein the control magnet system contains a magnetic coil.
